(19) United States
(12) Patent Application Publication
(10) Pub. No.: US 2026/0125538 A1
(43) Pub. Date: May 7, 2026

(54) METAL OXIDE PARTICLE MATERIAL, METHOD FOR PRODUCING SAME, SLURRY COMPOSITION, RESIN COMPOSITION, AND FILLER FOR SEALING MATERIAL FOR SEMICONDUCTOR PACKAGE

(71) Applicant: ADMATECHS CO., LTD., Miyoshi-shi (JP)

(72) Inventors: Shingi HIRANO, Miyoshi-shi (JP); Ryo HIBAKO, Miyoshi-shi (JP); Yuki ARAI, Miyoshi-shi (JP)

(73) Assignee: ADMATECHS CO., LTD., Miyoshi-shi (JP)

(21) Appl. No.: 19/440,765

(22) Filed: Jan. 6, 2026

Related U.S. Application Data
(63) Continuation of application No. PCT/JP2023/025142, filed on Jul. 6, 2023.

(51) Int. Cl. C08K 9/06; C01B 33/18; C08K 3/36; C09K 3/10; H10W 74/47

(52) U.S. Cl. CPC C08K 9/06; C01B 33/181; C08K 3/36; C09K 3/10; H10W 74/473; C01P 2004/61; C01P 2006/12; C01P 2006/19; C08K 2201/005; C08K 2201/006; C09K 2200/0247

(57) ABSTRACT

A metal oxide particle material contains a metal oxide as a main component and has: a D50 of 1.0 μm or more and 5.0 μm or less, the D50 being obtained by measuring a laser diffraction particle size distribution; a specific surface area of 1.0 m²/g or more and 30 m²/g or less; a coarse particle content of 300 ppm or less, the coarse particle content being a content of coarse particles having a particle diameter of 5 μm or more; and a hollow particle content of 4000 particles/10 mg or less, the hollow particle content being a content of hollow particles having a particle diameter of 5 μm or more. When a resin material is filled with the metal oxide particle material at a solid concentration of 60% by mass, a resultant resin composition has a viscosity of 170 Pa·s or less (at a shear velocity of 1 s⁻¹).

### CROSS REFERENCE TO RELATED APPLICATIONS

The present application is a Continuation Application of International Application No. PCT/JP2023/025142, filed on Jul. 6, 2023, which is incorporated herein by reference.

### TECHNICAL FIELD

The present disclosure relates to a metal oxide particle material, a method for producing the same, a slurry composition, a resin composition, and a filler for a sealing material for a semiconductor package.

### BACKGROUND ART

A semiconductor package is made by sealing a semiconductor IC chip with a sealing material in order to protect the IC chip from dust or moisture in air. The sealing material is a resin composition mainly formed from, for example, a resin having a high heat resistance and a high chemical resistance and particles of a metal oxide such as silica having a small thermal expansion coefficient or alumina, magnesia, or zinc oxide having a high thermal conductivity.

There are a plurality of methods for producing semiconductor packages according to various purposes and required performances. Packages required to have high functions and minute sizes such as those mounted in mobile devices are often produced by employing FOWLP or FOPLP technology.

### CITATION LIST

### Patent Literature

Patent Literature 1: JP2021-161008 (A)

### SUMMARY OF INVENTION

### Technical Problem

In FOWLP technology, packages as completed articles are closely similar to one another in terms of the structures themselves, but the production process therefor significantly differs among the companies that develop the packages. This difference in the production process significantly influences the performances of the packages as completed articles.

The production process is roughly divided into: a chip-first process in which a silicon die is placed first with a carrier at a wafer level being a start point; and a chip-last process in which a redistribution structure is formed first with the carrier being a start point. Out of these processes, the chip-first process is further subdivided into: a face-up process in which a circuit surface faces up when the silicon die is placed on the carrier; and a face-down process in which the circuit surface faces down when the silicon die is placed on the carrier.

Each of the various processes of FOWLP includes a step of polishing a surface of a semiconductor package including a sealing material after sealing an IC chip, in order to smooth the surface. In a case where hollow particles are present in the sealing material or in a case where cavities are formed owing to entry of air bubbles or the like into the sealing material, a problem arises in that a recess is formed in the surface of the package after the polishing so that the smoothness of the surface decreases or the appearance deteriorates, whereby the yield decreases.

In particular, in the case of a production process in which the surface of the semiconductor package is polished and then a redistribution layer is formed on the polished surface such as the face-up process, presence of hollow particles in the sealing material might lead to formation of a copper wire over a recess in the surface of the package. When the package is bulged or shrunk, i.e., deformed, owing to change in the temperature environment in this state, presence of a cavity portion of the recess poses a problem in that the copper wire is bent and broken. When there is no cavity portion, the periphery of the copper wire is enclosed by the sealing material, and the wire is not bent even upon such bulging or shrinkage, i.e., deformation. Conventionally, such a copper wire has had a large wire width of more than 10 μm, and thus the copper wire also has had a high rigidity and has not been easily bent. However, when the wire width becomes 10 μm or less as a result of causing the package to have a high function and to become minute, the rigidity of the copper wire becomes low. In view of this drawback, decrease of the content of hollow particles in the sealing material has been attracting attention.

Regarding a package for a server, a structure and a production method differ from those described above, and there is a case where: the package is stacked on an interposer or the like with a flip-chip structure; and then, the entirety is sealed. For a high-end package, there is a production method including two steps which are an underfill step for a narrow-gap portion below a chip and an over-molding step of protecting the entirety of the chip, and meanwhile, there is also a production method in which portions above and below a chip are collectively sealed. In particular, high fluidity is required for such collective sealing. For each of these types of packages as well, a step of polishing the surface of the package in order to smooth the surface has been employed, and, similar to the above description, a filler for a sealing material has been intensely required to have a low hollow particle content.

Along with the above required characteristics, semiconductor packages have been downsized, and wires have become minute. Accordingly, precise removal of solid coarse particles has also been required, and furthermore, the size of coarse particles required to be removed has been becoming small. Meanwhile, spherical particles having a large mode diameter are desirable from the viewpoint of the fluidity of a resin composition obtained by mixing a filler and a resin.

In view of these needs, a filler for a sealing material for a package such as one described above is required to have all of characteristics which are: the characteristic of having a large mode diameter; the characteristic that coarse particles have been precisely removed; the characteristic of having high filling ability with respect to a resin; and the characteristic of having a low hollow particle content.

Conventionally, metal oxide particles that have a D50 of 2 μm or more and from which solid particles (coarse particles) having a size of 5 μm or more have been removed, have been used as a filler for a sealing material for a package such as one described above. However, hollow particles have not been removed. Thus, when the wire width of a copper wire is 5 μm or less, the yield at the time of producing a package significantly decreases owing to a risk of wire breakage and deterioration of the appearance.

Metal oxide particles that have a D50 of 5 to 9 μm and from which solid particles (coarse particles) having a size of 10 μm or more have been removed, have also been widely used. Such metal oxide particles have a large D50 and thus accordingly exhibit high filling ability with respect to a resin. However, since coarse particles having a size of 5 to 10 μm are present, such metal oxide particles do not fill a narrow gap. Since hollow particles having a size of 5 to 10 μm are also present, this results in the risk of wire breakage and deterioration of the appearance. Thus, the yield at the time of producing a package comes to have an even smaller value.

As technologies related to removal of hollow particles, Patent Literature 1 describes: silica particles having a D50 of 100 nm or more and 200 nm or less and a specific surface area of 30 m²/g or less, the number of hollow particles having a size, i.e., diameter, of 2 μm or more being 1000 particles/0.1 g or less; and a method for producing the silica particles. However, since the D50 is small, the silica particles exhibit a high viscosity when being mixed with a resin, it is difficult for this filler to exhibit a high filling ability with respect to the resin, and a small thermal expansion coefficient and a high rigidity such as those required for the package are not exhibited.

In addition, although synthetic silica made through a wet synthesis process hardly contains hollow particles owing to the production process, the synthetic silica has a very sharp particle size distribution. Consequently, increase of the filling ability with respect to a resin is difficult. A technique that involves mixing wet synthetic silicas having different particle diameters is also conceivable to adjust the particle size distribution. However, in the first place, in the case of the wet synthesis process, the amount of hydroxy groups in the surfaces of particles is large, whereby increase of the filling ability with respect to a resin is difficult. A firing step may also be employed in order to decrease the amount of hydroxy groups in the surfaces. However, fusion between the particles occurs in this case. The problem of this fusion between the particles is solved to some extent by employing a crushing step. However, this step is long and also leads to very high costs.

The present disclosure has been completed in view of the above circumstances, and an object of the present disclosure is to provide a metal oxide particle material having a high filling ability into a resin material and having a low hollow particle content and a low coarse particle content, a method for producing the same, a slurry composition, a resin composition, and a filler for a sealing material for a semiconductor package.

### Solution to Problem

The present inventors conducted thorough studies in which a metal oxide particle material having a D50 set to be within an appropriate range and having a coarse particle content and a hollow particle content set, regarding the upper limit values thereof, to be within appropriate ranges was prepared and actually studied as a filler for a sealing material for a semiconductor package. As a result, the present inventors found that the metal oxide particle material had a high performance, thereby completing the following invention.

That is, a metal oxide particle material of the present disclosure for achieving the above object is a metal oxide particle material containing a metal oxide as a main component, wherein
the metal oxide particle material has
   a D50 of 1.0 μm or more and 5.0 μm or less, the D50 being obtained by measuring a laser diffraction particle size distribution,
   a specific surface area of 1.0 m²/g or more and 30 m²/g or less,
   a coarse particle content of 300 ppm or less, the coarse particle content being a content of coarse particles having a particle diameter of 5 μm or more, and
   a hollow particle content of 4000 particles/10 mg or less, the hollow particle content being a content of hollow particles having a particle diameter of 5 μm or more, and
when a resin material is filled with the metal oxide particle material at a solid concentration of 60% by mass, a resultant resin composition has a viscosity of 170 Pa·s or less (at a shear velocity of 1 s⁻¹).

Also, a metal oxide particle material production method of the present disclosure for achieving the above object is a method for producing the metal oxide particle material of the present disclosure, the method including:
a production step of causing a raw particle material containing a metal for forming the metal oxide particle material as a main component to pass through a high-temperature oxidizing atmosphere to deflagrate the raw particle material, and then cooling the raw particle material to produce a raw metal oxide particle material having a D50 of 1.0 μm or more and 5.0 μm or less; and
a classification step of classifying the raw metal oxide particle material until
   a content of coarse particles having a particle diameter of 5 μm or more becomes 300 ppm or less, and
   a content of hollow particles having a particle diameter of 5 μm or more becomes 4000 particles/10 mg or less.

### Advantageous Effects of Invention

The metal oxide particle material of the present disclosure exhibits excellent flowability, including a permeation characteristic into narrow gaps, when dispersed in a resin material to form a resin composition. In addition, the metal oxide particle material eliminates the risk of wire breakage and prevents deterioration of the appearance with respect to a package in which a copper wire has a wire width of 10 μm or less and a package for a server, and thus is particularly useful as a filler for a sealing material for a semiconductor package.

### DESCRIPTION OF EMBODIMENTS

A metal oxide particle material, a method for producing the same, a slurry composition, a resin composition, and a filler for a sealing material for a semiconductor package according to the following embodiment of the present disclosure will be described in detail. The metal oxide particle material according to the present embodiment may be dispersed in a resin material to form a resin composition or may be dispersed in a dispersion medium in liquid form to form a slurry composition. The metal oxide particle material is particularly suitably usable as a filler for a sealing material for a semiconductor package.

### (Metal Oxide Particle Material and Filler for Sealing Material for Semiconductor Package)

The metal oxide particle material according to the present embodiment is suitably usable directly as a filler for a sealing material for a semiconductor package. The semiconductor to which the metal oxide particle material is applied is preferably one that is produced by employing FOWLP or FOPLP technology.

The metal oxide particle material according to the present embodiment contains a metal oxide as a main component. The phrase “contains a metal oxide as a main component” means that 50% or more of the metal oxide particle material is formed from a metal oxide with the mass of the metal oxide particle material being regarded as a reference. The content of the metal oxide is preferably 60% or more, 70% or more, 80% or more, 90% or more, 95% or more, or the like. Determination is made for each of individual metal oxide particle materials in relation to whether the metal oxide particle material contains a metal oxide as a main component. Therefore, there is a case where a particle material containing a metal oxide as a main component and a particle material that does not contain a metal oxide as a main component are present. In this case, a mixture of the metal oxide particle material according to the present embodiment and another particle material is obtained. Examples of the metal oxide include oxides each containing one or a plurality of Si, Al, Zr, Ti, and the like. The metal oxide may be an amorphous substance, a crystalline substance, or a mixture of both substances.

The metal oxide particle material has a D50 of 1.0 μm or more and 5.0 μm or less, the D50 being obtained by measuring a laser diffraction particle size distribution. Examples of the lower limit value of the D50 include 1.2 μm, 1.4 μm, 1.6 μm, 1.8 μm, 2.0 μm, and 2.2 μm, and examples of the upper limit value of the D50 include 4.8 μm, 4.6 μm, 4.4 μm, 4.2 μm, 4.0 μm, 3.8 μm, 3.6 μm, and 3.4 μm. These upper limit values and these lower limit values may be arbitrarily combined with each other. The D50 is a value obtained by measuring a laser diffraction particle size distribution and is a particle diameter corresponding to 50% on a volume basis among particle diameters arranged in ascending order. Meanwhile, a D100 is a particle diameter corresponding to 100% among the particle diameters arranged in ascending order. Each of the values of the D50 and the D100 is a value calculated as a numerical value within a range between measurement limits based on the measurement of the diffraction laser particle size distribution. In actuality, coarse particles or fine particles that are undetectable in the measurement of the laser diffraction particle size distribution are present. Therefore, presence of a particle having a particle diameter larger than the value of the D100 poses no contradiction.

When a resin material is filled with the metal oxide particle material at a solid concentration of 60% by mass, a resultant resin composition has a viscosity of 170 Pas or less (at a shear velocity of 1 s⁻¹). As the resin material, an epoxy resin obtained by mixing a bisphenol A epoxy resin and a bisphenol F epoxy resin at a ratio of 1:1 is used (e.g., ZX-1059 manufactured by NIPPON STEEL Chemical & Material Co., Ltd.).

The value of the D50 enables control of the particle size distribution by controlling a production condition for the metal oxide particle material and is also adjustable by performing a classification operation or adding a particle material having another particle size distribution. Suitable examples of the classification operation include centrifugal separation in which a cyclone or the like is used. The classification operation may be performed also on the particle material to be added.

The metal oxide particle material has a linseed oil absorption amount of preferably 2.7 g/15 g or less, more preferably 2.5 g/15 g or less, and further preferably 2.3 g/15 g or less. The linseed oil absorption amount is obtained as follows. That is, a linseed oil addition amount (g) at which, as a result of dripping linseed oil drop by drop onto 15 g of the metal oxide particle material, the metal oxide particle material has been visually confirmed to have become fluidic is measured, and the linseed oil absorption amount is calculated as “linseed oil addition amount (g)÷mass of particle material (15 g)”.

The metal oxide particle material has a coarse particle content of 300 ppm or less, the coarse particle content being a content of coarse particles having a particle diameter of 5 μm or more. The coarse particle content may be 200 ppm or less, 100 ppm or less, 50 ppm or less, 30 ppm or less, or the like. The particle diameter of the coarse particles may be 4.5 μm, 4 μm, or the like. Such coarse particles are removable by performing a classification operation as described later, and a cyclone is usable, for example.

The metal oxide particle material has a specific surface area of 1.0 m²/g or more and 30 m²/g or less. Examples of the lower limit value of the specific surface area include about 1.1 m²/g, 1.2 m²/g, 1.4 m²/g, 1.6 m²/g, 1.8 m²/g, 2.0 m²/g, 2.5 m²/g, and 3.0 m²/g, and examples of the upper limit of the specific surface area include about 27.5 m²/g, 25 m²/g, 22.5 m²/g, 20 m²/g, 17.5 m²/g, 15 m²/g, 12.5 m²/g, 10 m²/g, 7.5 m²/g, 5.0 m²/g, and 4.5 m²/g. The specific surface area is a value measured through the BET method in which nitrogen is used. A smaller value of the specific surface area leads to a lower viscosity in the case of using the metal oxide particle material for a slurry composition or the like, and thus is more preferable. A control method for the specific surface area is not particularly limited, and it is possible to employ a method in which the metal oxide particle material is synthesized under such a condition as to decrease the amount of fine powder or a method in which the retention time in a classifier is controlled to be long during classification to decrease the amount of fine powder, thereby decreasing the specific surface area.

The hollow particle content is 4000 particles/10 mg or less in terms of the number of hollow particles having a particle diameter of 5 μm or more. The number of hollow particles of 5 μm or more is 4000 particles/10 mg or less. The upper limit value of this number may be set to 3500 particles/10 mg, 3000 particles/10 mg, 2500 particles/10 mg, 2000 particles/10 mg, 1500 particles/10 mg, 1000 particles/10 mg, 750 particles/10 mg, 500 particles/10 mg, 250 particles/10 mg, 200 particles/10 mg, 150 particles/10 mg, 100 particles/10 mg, 50 particles/10 mg, 40 particles/10 mg, or 30 particles/10 mg. The number of hollow particles may be defined as the number of hollow particles of 2 μm or more by using the above numerical values. As described later, for solid particles and hollow particles, ranges of diameters of particles to be removed according to different principles may be set. Thus, the lower limit values of the respective diameters of the particles may be set to different values.

The number of the hollow particles may be decreased through a method including classification by using a filter or a classification operation based on the difference in specific gravity in which a liquid is used. Specific explanations will be given in the section regarding the production method described later. 4000 particles/10 mg which is the upper limit value of the number of the hollow particles is a value much smaller than 300 ppm which is the upper limit value of the coarse particle content.

The number of the hollow particles is obtained through a method including dispersing the metal oxide particle material in a liquid and counting the number of the hollow particles by using an image-analyzing particle size distribution meter. A ratio (ns/nf) of a refractive index ns of the liquid to a refractive index nf of the metal oxide particle material is specified to be 0.98 to 1.02.

When an insoluble solid is dispersed in a certain liquid, in a case where the refractive index of the solid is approximately equal to the refractive index of the liquid, the solid becomes less likely to be visually recognized in the liquid. Thus, even though the solid is dispersed, the liquid looks transparent.

Meanwhile, the hollow particles in the metal oxide particle material have gaps therein and thus are optically observable because of the difference from the refractive index of the liquid. Consequently, a state where the solid particles are transparent and are less likely to be visually recognized and the hollow particles are specifically visually recognizable is obtained, whereby the hollow particles become countable.

The total amount of an alkali metal and an alkaline earth metal is 100 ppm or less, preferably 80 ppm or less, more preferably 50 ppm or less, and particularly preferably 30 ppm or less. This total amount is realized by purifying materials to be used at the time of producing the metal oxide particle material. An alkali metal and an alkaline earth metal are oxidized to be, for example, eluted or precipitated as ions. Thus, application to a sealing material for a semiconductor device or the like is assumed to unexpectedly influence the semiconductor device. For example, with the electrical conductivity (EC) of a water extract being taken into account, the EC is desirably 10 μS/cm or less. In order to decrease this value, the alkali metal content and the alkaline earth metal content desirably become low. This is why the above range of the total amount is set. The EC is measured as follows. That is, particles of the metal oxide are suspended in ion exchanged water (electrical conductivity: 1 μS/cm or less) to obtain a 10% slurry. In this state, the 10% slurry is supplied into a pressure-resistant container and is shaken at room temperature for 30 minutes. Thereafter, centrifugation is performed, and the resultant supernatant is measured by using an electrical conductivity meter (EC meter) ES-51 manufactured by HORIBA, Ltd. The EC is the electrical conductivity obtained at this time.

The metal oxide particle material according to the present embodiment has preferably been subjected to surface treatment with a surface treatment agent such as a silane compound or a silazane compound. The silane compound and the silazane compound are not particularly limited, and a silane compound or a silazane compound having an appropriate functional group may be selected as necessary to perform surface treatment. The surface treatment may also be performed with a combination of two or more types of compounds selected from such silane compounds and silazane compounds.

The metal oxide particle material according to the present embodiment desirably has an x-ray generation amount of 0.001 c/cm²·h or less. In particular, 3 ppb or less (further desirably 1 ppb or less) of uranium or thorium as an x-ray source is desirable.

### (Method for Producing Metal Oxide Particle Material)

A metal oxide particle material production method according to the present embodiment includes a production step, a classification step, and another step employed as necessary. The metal oxide particle material production method according to the present embodiment is a method for suitably producing the above metal oxide particle material according to the present embodiment.

### Production Step

The production step is a step of combusting a raw particle material to produce a raw metal oxide particle material. The raw particle material having been produced has a volume-average particle diameter of 1 μm or more and 5 μm or less. This range of the volume-average particle diameter is identical to the range of the volume-average particle diameter of the metal oxide particle material to be produced. Here, coarse particles to be removed in the classification step which is subsequently performed for removing coarse particles are preferably as few as possible, and this is why the raw particle material has a volume-average particle diameter equivalent to the volume-average particle diameter of the metal oxide particle material to be produced.

This step is a so-called VMC method and allows easy obtainment of a high-sphericity dense raw metal oxide particle material having excellent electrical characteristics. The raw particle material is selected according to the type of the metal oxide to be contained in the metal oxide particle material to be produced. For example, in a case where the metal oxide is silica, metal silicon is used as the raw particle material. Alternatively, in a case where the metal oxide is alumina, metal aluminum is used as the raw particle material. Alternatively, in a case where the metal oxide is zirconia, metal zirconium is used as the raw particle material. In a case where a plurality of metal elements are contained in the metal oxide, metals corresponding to the elements are contained in the raw particle material. In the case where such a plurality of metals are contained, the raw particle material may be a mixture of particle materials formed from the respective metals or may contain two or more metal elements in one particle.

The VMC method is a method including: combusting a combustible agent (hydrocarbon gas or the like) by a burner in an oxygen-containing atmosphere to form chemical flame as a high-temperature atmosphere; and supplying, in such an amount as to form a dust cloud, the raw particle material into the chemical flame to deflagrate the raw particle material, thereby obtaining a raw metal oxide particle material. The high-temperature atmosphere is desirably an atmosphere at 2000° C. or more.

Actions in the VMC method will be described as follows. First, a container is filled with an oxygen-containing gas as a reaction gas, and chemical flame is formed in the reaction gas. Then, the raw particle material is supplied into the chemical flame to form a dust cloud. Consequently, the chemical flame provides thermal energy to the surface of the raw particle material. Thus, the temperature of the surface of the metal forming the raw particle material increases, and vapor of the contained metal is spread from the surface of the raw particle material to the surroundings. This vapor reacts with the oxygen gas and is ignited, whereby flame is generated. Heat generated by this flame further promotes vaporization of the raw particle material, and the generated vapor and the oxygen gas are mixed with each other, whereby ignition propagation successively occurs. Therefore, since a smaller particle diameter of the raw particle material leads to a larger specific surface area and a higher reactivity, a smaller particle diameter of the raw particle material leads to less supply energy.

By progression of successive ignition in this manner, the raw particle material itself is fractured and scattered to promote flame propagation. After the combustion, the generated gas is naturally cooled, whereby a cloud of the metal contained in the raw particle material is formed. The obtained raw metal oxide particle material is collected by a bag filter, an electric dust collector, or the like.

The VMC method is based on the principle of dust explosion. Through the VMC method, a large amount of the raw metal oxide particle material is instantly obtained. The obtained raw metal oxide particle material has a substantially perfect spherical shape. By adjusting the particle diameter and the supply amount of the raw particle material to be supplied, the temperature of the flame, and the like, the particle diameter distribution of the raw metal oxide particle material to be obtained is adjusted. The raw particle material may be composed of a metal alone or may be obtained by adding particles formed from a metal oxide (e.g., silica). As the metal oxide particles to be simultaneously supplied, metal oxide particles having been obtained through this method are used, whereby the purity of the raw metal oxide particle material to be obtained is maintained.

The raw particle material may be subjected to surface treatment with a silane compound, a silazane compound, or the like. The type of the silane compound that is usable is not particularly limited, and, for example, a compound to be used in a surface treatment step described later is usable.

The raw particle material is combusted by being supplied into the flame in a state of being dispersed in a carrier. The speed of supplying the raw particle material into the flame is not particularly limited. As the carrier, a gas such as nitrogen gas, argon gas, or air or a liquid such as water or an alcohol may be selected. The manner of the dispersion is not particularly limited, but, in a case where the raw particle material is dispersed in a liquid, the resultant dispersion is preferably sprayed in a mist form to be supplied into the flame. For example, the raw particle material in an amount that is about 10% to 80% of the amount of the entirety on a volume basis is preferably contained.

As the flame, flame in an oxidizing atmosphere is used. Examples of the flame include flame obtained by combusting a combustible gas such as LPG, ammonia gas, or hydrogen gas in an atmosphere containing oxygen in excess. In addition, the flame also includes thermal plasma.

The raw particle material formed from the metal and supplied into the flame vaporizes by the combustion and is rapidly cooled, whereby raw material silica particles formed from silica are obtained. The obtained raw material silica particles are collected by a bag filter or the like.

### Classification Step

The classification step is a step of classifying the raw metal oxide particle material until the raw metal oxide particle material comes to have a particle size distribution in which: the content of the coarse particles is the above corresponding upper limit value or less; and the content of the hollow particles having a particle diameter of 5 μm or more is the above corresponding upper limit value or less. The coarse particles include solid particles and hollow particles.

The classification operation is performed through, for example, centrifugal separation in a gas or in a solvent, separation according to specific gravities in a liquid, or a dry or wet process in which a sieve is used. This step is repeatedly performed until the desired particle size distribution is obtained through one time of such classification operation.

The centrifugal separation is a method suitable for removing the solid particles among the coarse particles. The solvent to be used in the centrifugal separation is desired to have a low viscosity. Examples of the solvent include methyl ethyl ketone (MEK), methyl isobutyl ketone (MIBK), and toluene. By performing the centrifugal separation in a state where the raw metal oxide particle material is dispersed at a concentration of about 10% by mass to 30% by mass (in particular, 15% by mass to 25% by mass) in MEK, the solid coarse particles are separated with high precision. In such wet-process centrifugal separation, centrifugal force is applied to the slurry to precipitate and remove the coarse particles, whereby the coarse particles are separated.

In order to separate the hollow particles among the coarse particles, the hollow particles having a low specific gravity are preferably separated after the raw metal oxide particle material is dispersed in a liquid. The separation in the liquid is preferably performed through removal of the hollow particles present in a supernatant obtained by leaving the resultant dispersion at rest or by applying centrifugal force to the resultant dispersion (hollow particle separation step). As the liquid to be used, a liquid identical to the liquid to be used in the centrifugal separation is usable. Among the coarse particles, the solid particles swiftly precipitate, and the hollow particles slowly precipitate or do not precipitate. Thus, the supernatant may be removed along with the above operation for removing the coarse particles to simultaneously remove the solid particles among the coarse particles and the hollow particles among the coarse particles.

In the case of employing classification with a filter, the classification is performed in a dispersion slurry state obtained by dispersing the raw metal oxide particle material in a solvent. The classification operation with a filter is desirably performed a plurality of times. In the case of performing the classification operation with a filter a plurality of times, the classification operation with a filter is preferably performed while change from a filter having a large opening diameter to a filter having a small opening diameter is being made.

### Another Step

A surface treatment step may be employed. The surface treatment step may be performed at a timing before the classification step is executed on the raw metal oxide particle material produced through the production step, after the execution, or during the execution.

The surface treatment step is a step of performing surface treatment on the raw metal oxide particle material with a surface treatment agent such as a silane compound or a silazane compound. A functional group derived from the surface treatment agent is introduced to a surface of the metal oxide particle material eventually produced, or the surface treatment agent is adhered to the surface.

The surface treatment is performed by directly (either in liquid form or gas form) bringing the surface treatment agent into contact with the surfaces of the particles or by achieving the contact in a state where dissolving in a certain solvent is performed. In the surface treatment, heating may be performed after the surface treatment agent is brought into contact with the particles. In a case where the classification operation in a liquid is employed in the aforementioned classification step, the surface treatment step may be performed in the liquid.

The amount of the surface treatment agent with which the surface treatment is performed is not particularly limited. For example, in a case where a substance that reacts with the surfaces of particles and that is exemplified by a silane compound and a silazane compound is used as a surface treatment agent, a reaction amount corresponding to an amount that is, for example, 100%, 75%, 50%, or 25% with the amount of OH groups present in the surfaces of particles to be treated being regarded as a reference may be selected. An excessive amount that is more than 100% (120%, 150%, or the like) may also be selected. In this case, an unreacted portion of the surface treatment agent remains in the surfaces of the particles.

The silane compound is not particularly limited, and examples thereof include compounds having phenyl groups, alkyl groups, vinyl groups, methacrylic groups, epoxy groups, phenylamino groups, amino groups, styryl groups, and the like.

### (Resin Composition)

The resin composition according to the present embodiment is obtained by dispersing the above metal oxide particle material in a resin material (also encompassing a resin material precursor). The mixing ratio between the metal oxide particle material and the resin material is not particularly limited. The resin material is not particularly limited, and examples thereof include epoxy resins, acrylic resins, silicone resins, and the like. The resin material may be a resin material precursor having yet to be cured.

### (Slurry Composition)

The slurry composition according to the present embodiment is obtained by mixing the above metal oxide particle material and a dispersion medium in liquid form (a solvent, a resin material precursor, or the like). The mixing ratio between the metal oxide particle material and the dispersion medium is not particularly limited. Examples of the dispersion medium include, in addition to the aforementioned resin material precursor, MEK, MIBK, hexane, alcohols such as isopropanol, and the like.

### EXAMPLES

The metal oxide particle material and the method for producing the same of the present disclosure will be described in detail based on the following Examples.

### Test Example 1

A raw particle material formed from metal silicon was supplied into a high-temperature atmosphere to be deflagrated and then was cooled. Consequently, a raw metal oxide particle material formed from silica was obtained (production step). The raw metal oxide particle material had: a D50 of 2.0 μm, the D50 being obtained by measuring a laser diffraction particle size distribution; and a specific surface area of 2.0 m²/g.

A cyclone was used to remove coarse particles having a particle diameter of 5 μm or more from the raw metal oxide particle material until the coarse particle content became 300 ppm or less (classification step). After the coarse particles were removed, 100 g of the obtained particle material was put into a 500-mL plastic container, 50 g of isopropyl alcohol was supplied thereinto as a solvent, and dispersion was performed for 5 minutes by using a commercially available homogenizer such that the particles were evenly dispersed. Consequently, a slurry was made. Thereafter, the slurry was left at rest for 1.2 hours, and the resultant supernatant layer (1 cm from the liquid surface, 95% in the depth direction) was removed by using a dropper. In the supernatant layer, hollow particles having gathered to the supernatant layer owing to the difference in specific gravity between the hollow particles and solid particles had been present. Thus, the hollow particles were effectively removed (the hollow particle separation step of the classification step).

The remainder obtained through the removal of the supernatant layer was transferred to a metallic vat container and was dried at 130° C. for 8 hours by a quasi-explosion-proof dryer. Consequently, 41 g of a metal oxide particle material was obtained. Thereafter, in order to decrease the viscosity to be exhibited at the time of mixing the metal oxide particle material with a resin material, surface treatment was performed with 3-methacryloxypropyltrimethoxysilane as a surface treatment agent (surface treatment step). This metal oxide particle material was used as a test sample in the present Test Example.

### Test Example 2

A metal oxide particle material was prepared through the same operations as those in Test Example 1, except that the hollow particle separation step was not performed. This metal oxide particle material was used as a test sample in the present Test Example.

### Test Example 3

A metal oxide particle material was prepared through the same operations as those in Test Example 1, except that neither the hollow particle separation step nor the surface treatment step was performed. This metal oxide particle material was used as a test sample in the present Test Example.

### Test Example 4

Crushed silica was used as a raw material and was supplied into melting flame to be made into a spherical shape. The resultant article had a D50 of 3.5 μm and a specific surface area of 1.5 m²/g. Coarse particles of 10 μm or more were removed from this article according to the method in Test Example 1 to prepare a metal oxide particle material which was then used as a test sample in the present Test Example.

### Test Example 5

Crushed silica was used as a raw material and was supplied into melting flame to be made into a spherical shape. The resultant article had a D50 of 5.0 μm and a specific surface area of 5.0 m²/g. Coarse particles of 10 μm or more were removed from this article according to the method in Test Example 1 to prepare a metal oxide particle material which was then used as a test sample in the present Test Example.

### Test Example 6

Crushed silica was used as a raw material and was supplied into melting flame to be made into a spherical shape. The resultant article had a D50 of 10 μm and a specific surface area of 3.5 m²/g. Coarse particles of 25 μm or more were removed from this article according to the method in Test Example 1 to prepare a metal oxide particle material which was then used as a test sample in the present Test Example.

### Test Example 7

Based on Test Example 1 in JP2021-161008 (A), surface treatment was performed on a metal oxide particle material (D50: 150 nm, D100: 270 nm, specific surface area: 21.3 m/g, the number of hollow particles of 2 μm or more: 104 particles/0.1 g (=10 particles/10 mg)) with 3-methacryloxypropyltrimethoxysilane. This metal oxide particle material was used as a test sample in the present Test Example.

Test Example 1 in JP2021-161008 (A) was as follows. A raw particle material that was formed from silica produced through the VMC method and that had a volume-average particle diameter of 300 nm and a specific surface area of 17.8 m²/g was used.

Surface treatment was performed on the raw particle material with N-phenyl-3-aminopropyltrimethoxysilane as a silane compound. The amount of the silane compound was 2% with the mass of the raw particle material being regarded as a reference.

The obtained particle material was dispersed in MEK to obtain a liquid dispersion having a solid concentration of 20% by mass. The liquid dispersion was subjected to precipitation and removal of coarse particles through decantation in a centrifugal field under conditions of a centrifugal acceleration of 1700 G and a retention time of 2.8 minutes. (Retention time in centrifugal field: minutes)/(viscosity of classified slurry: mPa·s) was 1.4, and (centrifugal acceleration: G)/(viscosity of classified slurry: mPa·s) was 850. Thereafter, filters having respective opening diameters of 5 μm, 3 μm, and 1 μm were used to perform classification one time per filter, thereby removing hollow particles. The post-classification liquid dispersion was left at rest and dried for 30 minutes in a dryer at 160° C. A metal oxide particle material resulting from the drying was used as a test sample in the present Test Example.

### Test Example 8

A 500-mL reaction container equipped with a stirrer was set in a thermostatic chamber, and 43 g of ethanol, 46 g of water, and 51 g of 25%-by-mass ammonia water were put into the reaction container and were heated to 50° C. while being mixed by the stirrer. Then, while the resultant liquid mixture was being stirred, 105 g of tetraethoxysilane was continuously added over 11 minutes. After the addition, the resultant solution was filtered to obtain silica particles. Thereafter, the silica particles were dried by a quasi-explosion-proof dryer at 130° C. for 8 hours and then were fired by using a firing furnace at 1000° C. for 12 hours. The heating time in the firing was set to 2 hours, and the fired silica particles were naturally cooled over a retention time of 12 hours. The obtained metal oxide particle material had a spherical shape and had a D50 of 0.7 μm. This metal oxide particle material was used as a test sample in the present Test Example.

### Test Example 9

A metal oxide particle material was prepared through the same production method as that in Test Example 8, except that the amount of ethanol was changed to 75 g. This metal oxide particle material was used as a test sample in the present Test Example. The obtained metal oxide particle material had a spherical shape and had a D50 of 1.0 μm.

### Test Example 10

A metal oxide particle material was prepared through the same production method as that in Test Example 8, except that the amount of ethanol was changed to 100 g. This metal oxide particle material was used as a test sample in the present Test Example. The obtained metal oxide particle material had a spherical shape and had a D50 of 2.0 μm.

### Test Example 11

A raw particle material (formed from silica and having a volume-average particle diameter of 2.0 μm) obtained through the VMC method was dispersed in isopropyl alcohol by using a dispersing machine of a high-pressure type, whereby a liquid dispersion (dispersion slurry) having a solid concentration of 30% by mass was obtained.

By utilizing the difference in precipitation speed among particle diameters in the liquid dispersion, solid coarse particles of 3 μm or more were removed by a centrifugal separation machine.

Next, filters having respective opening diameters of 7 μm, 5 μm, and 3 μm were used to perform classification one time per filter. Thus, coarse particles of 3 μm or more including hollow particles were removed, whereby a post-classification slurry composition was obtained. The post-classification slurry was dried by using a dryer to obtain a silica particle material which was then used as a test sample in the present Example.

### Test Example 12

The same metal oxide particle material as that in Test Example 1 was used as a test sample in the present Test Example, except that: only the hollow particle removal step was performed as the classification step; and the surface treatment step was not performed.

### Test Example 13

To 100 g of the raw metal oxide particle material obtained through the production step in Test Example 1, 10 g of a sample obtained by merely drying the material after the hollow particle separation step in Test Example 1 was added and mixed. The resulting mixture was used as the test sample in the present Test Example.

### Test Example 14

A metal oxide particle material was obtained in the same manner as in Test Example 1, except that a step of causing passage through a filter having an opening diameter of 5 μm three times was employed instead of the hollow particle separation step. This metal oxide particle material was used as a test sample in the present Test Example. A sample having been caused to pass through the filter only one time had a hollow particle content of 4200 particles/10 mg.

### Test Example 15

A metal oxide particle material was obtained in the same manner as in Test Example 1, except that a step of causing passage through the filter having the opening diameter of 5 μm two times was employed instead of the hollow particle separation step. This metal oxide particle material was used as a test sample in the present Test Example. A sample having been caused to pass through the filter only one time had a hollow particle content of 980 particles/10 mg.

### (Evaluation)

For each of the test samples in the respective Test Examples, Table 1 indicates: a D50; a specific surface area (SSA); a lower limit value (top cut point) of the particle diameters of the removed coarse particles; whether surface treatment with methacrylic silane was performed or not; a viscosity when an epoxy resin was filled; a content of coarse particles having a particle diameter of 5 μm or more; a content of hollow particles having a particle diameter of 5 μm or more; and an extent of imperfection when a semiconductor package was made.

The D50 is a value obtained by measuring a laser diffraction particle size distribution. The SSA is a value measured through the BET method by using nitrogen gas. The viscosity when an epoxy resin was filled is a viscosity at 25° C. (at a shear velocity of 1 s⁻¹) when the test sample was evenly dispersed at a solid concentration of 60% by mass in an epoxy resin (ZX-1059 manufactured by NIPPON STEEL Chemical & Material Co., Ltd.).

The contents of coarse particles and hollow particles were calculated from values counted through image analysis in a state where the test sample was dispersed in a liquid. Regarding the number of coarse particles, the number of coarse particles contained in a liquid dispersion obtained by dispersing the test sample at a concentration of 3% by mass in MEK as a dispersion medium was counted by using an image processing apparatus (Sysmex Corporation: FPIA-3000). The amount of the liquid dispersion for the counting was set to such an amount as to disperse 10 g of the test sample.

The number of hollow particles was measured by employing the method described in JP2022-117398 (A) (paragraph). Specifically, an image-analyzing particle size distribution meter (IF-3200 manufactured by JASCO INTERNATIONAL CO., LTD.) was used as a hollow particle detection apparatus. First, a liquid mixture obtained by adjusting the mass ratio of toluene to acetone to 3:1 was used as a dispersion medium, and test solutions in which the concentration of the test sample was 30 mg/mL were prepared. Thereafter, ultrasonication was performed on the obtained test solutions for 2 minutes. Each of the test solutions was subjected to image detection by the above detection apparatus, and the number of hollow particles in the test sample was counted (the number of hollow particles in 10 mg of the test sample was indicated with the unit being particle). In addition, the major axes of the respective hollow particles were measured, and an average value of the measured values was obtained. The detection apparatus used had a lens magnification of 4-fold, and the thickness of a spacer of a measurement unit was set to 300 μm. Images were repeatedly taken by using a CMOS camera mounted on the apparatus until an amount corresponding to 10 mg of silica was obtained. The obtained images were analyzed. Out of the obtained images, only results with the circularities being 95% or more were extracted and analyzed in order to extract only hollow particles. In a case where the number of the coarse particles was 500 ppm or more, “XX” was indicated. In a case where the number of the hollow particles was 10000 particles or more, the corresponding entries in Table 1 are marked as “XX” to indicate that the values exceed the acceptable upper limits.

The extent of imperfection when a semiconductor package was made was calculated from the number of hollow particles having a size of 5 μm or more and having been confirmed when a sample was observed over a range thereof measuring 1 cm×1 cm by using a microscope, the sample having resulted from polishing a cured product obtained by: kneading each of the test samples with a liquid resin and a curing agent; and heating and curing the resultant mixture. The preparation of the cured product was performed by: blending 3.8 g of ZX-1059 and 1 g of a curing agent ETHACURE 300 (Mitsui Fine Chemicals, Inc.) with 16 g of the test sample; and heating and curing the resultant mixture at 175° C. for 2 hours.

When the number of hollow particles having a size of 5 μm or more confirmed in the observed area was less than 10, the package defect rate was evaluated as “Good”. When this number was 10 or more and less than 300, the package defect rate was evaluated as “Acceptable”. When this number was 300 or more, the package defect rate was evaluated as “Poor”. When a very high viscosity of 170 Pa·s or more was exhibited at the time of kneading with the liquid resin and the curing agent, the package was evaluated as “Unable to be made into PKG”.

TABLE 1

| | Test | Test | Test | Test | Test |
|---|---|---|---|---|---|
| Item | Example 1 | Example 2 | Example 3 | Example 4 | Example 5 |
| D50 (μm) | 1.8 | 1.8 | 1.8 | 3.5 | 5 |
| SSA (m²/g) | 3.8 | 3.8 | 3.8 | 1.5 | 4 |
| Top cut point | 5 | 5 | 5 | 10 | 20 |
| (μm) | | | | | |
| Whether | Performed | Performed | Not | Performed | Performed |
| surface | | | performed | | |
| treatment | | | | | |
| (with | | | | | |
| methacrylic | | | | | |
| silane) was | | | | | |
| performed or | | | | | |
| not | | | | | |
| Filling | 50 | 50 | 200 | 50 | 30 |
| ability at 60 | | | | | |
| wt % with | | | | | |
| respect to | | | | | |
| epoxy resin | | | | | |
| (ZX-1059) | | | | | |
| (Pa · s) | | | | | |
| Linseed oil | 2.2 | 2.2 | 2.2 | 3.9 | — |
| absorption | | | | | |
| amount (g/15 g | | | | | |
| of powder) | | | | | |
| Content of | 10 | 10 | 10 | XX | XX |
| coarse | | | | | |
| particles of 5 | | | | | |
| μm or more | | | | | |
| (ppm/10 g) | | | | | |
| Content of | 72 | 4200 | 4200 | XX | XX |
| hollow | | | | | |
| particles | | | | | |
| having | | | | | |
| diameter of 5 | | | | | |
| μm or more | | | | | |
| (particles/10 | | | | | |
| mg) | | | | | |
| Package defect | Good | Poor | Unable to | Poor | Poor |
| rate (—) | | | be made | | |
| | | | into PKG | | |

| | Test | Test | Test | Test | Test |
|---|---|---|---|---|---|
| Item | Example 6 | Example 7 | Example 8 | Example 9 | Example 10 |
| D50 (μm) | 10 | 0.2 | 0.7 | 1.0 | 2.0 |
| SSA (m²/g) | 3 | 25 | 3.8 | 2.7 | 1.3 |
| Top cut point | 25 | 2 | — | — | — |
| (μm) | | | | | |
| Whether | Performed | Performed | Performed | Performed | Performed |
| surface | | | | | |
| treatment | | | | | |
| (with | | | | | |
| methacrylic | | | | | |
| silane) was | | | | | |
| performed or | | | | | |
| not | | | | | |
| Filling | 20 | 3200 | XX | 15000 | 10000 |
| ability at 60 | | | | | |
| wt % with | | | | | |
| respect to | | | | | |
| epoxy resin | | | | | |
| (ZX-1059) | | | | | |
| (Pa · s) | | | | | |
| Linseed oil | 2.1 | 4.9 | 5.9 | 5.7 | 5.0 |
| absorption | | | | | |
| amount (g/15 g | | | | | |
| of powder) | | | | | |
| Content of | XX | 10 | 10 | 10 | 10 |
| coarse | | | | | |
| particles of 5 | | | | | |
| μm or more | | | | | |
| (ppm/10 g) | | | | | |
| Content of | XX | 10 | 23 | 40 | 45 |
| hollow | | | | | |
| particles | | | | | |
| having | | | | | |
| diameter of 5 | | | | | |
| μm or more | | | | | |
| (particles/10 | | | | | |
| mg) | | | | | |
| Package defect | Poor | Unable to | Unable to | Unable to | Unable to |
| rate (—) | | be made | be made | be made | be made |
| | | into PKG | into PKG | into PKG | into PKG |

| | Test | Test | Test | Test | Test |
|---|---|---|---|---|---|
| Item | Example 11 | Example 12 | Example 13 | Example 14 | Example 15 |
| D50 (μm) | 1.2 | 2.0 | 2.0 | 1.6 | 2.0 |
| SSA (m²/g) | 5.0 | 2.0 | 2.0 | 4.2 | 3.6 |
| Top cut point | 3 | 5 | 5 | 5 | 5 |
| (μm) | | | | | |
| Whether | Performed | Performed | Performed | Performed | Performed |
| surface | | | | | |
| treatment | | | | | |
| (with | | | | | |
| methacrylic | | | | | |
| silane) was | | | | | |
| performed or | | | | | |
| not | | | | | |
| Filling | 180 | 400 | 400 | 60 | 45 |
| ability at 60 | | | | | |
| wt % with | | | | | |
| respect to | | | | | |
| epoxy resin | | | | | |
| (ZX-1059) | | | | | |
| (Pa · s) | | | | | |
| Linseed oil | 3.4 | 2.8 | 2.8 | 2.2 | 2.2 |
| absorption | | | | | |
| amount (g/15 g | | | | | |
| of powder) | | | | | |
| Content of | 10 | 10 | 10 | 10 | 10 |
| coarse | | | | | |
| particles of 5 | | | | | |
| μm or more | | | | | |
| (ppm/10 g) | | | | | |
| Content of | 31 | 100 | 4000 | 65 | 980 |
| hollow | | | | | |
| particles | | | | | |
| having | | | | | |
| diameter of 5 | | | | | |
| μm or more | | | | | |
| (particles/10 | | | | | |
| mg) | | | | | |
| Package defect | Unable to | Unable to | Unable to | Good | Acceptable |
| rate (—) | be made | be made | be made | | |
| | into PKG | into PKG | into PKG | | |

As is obvious from the table, each of Test Examples 1, 14, and 15 had a small package defect rate and was found to exhibit an excellent performance as a filler for a sealing material for a semiconductor package. These three Test Examples satisfied all of the requirements (1) to (5) described below. Therefore, satisfaction of all of these requirements has been inferred to lead to exhibition of a high performance as a filler for a sealing material for a semiconductor package.

(1) Test Examples 1 to 5 and 9 to 15 in each of which the D50 was 1.0 μm or more and 5.0 μm or less, (2) Test Examples 1 to 15 in each of which the SSA was 1.0 m²/g or more and 30 m²/g or less, (3) Test Examples 1 to 3 and 7 to 15 in each of which the content of the coarse particles having a particle diameter of 5 μm or more was 300 ppm or less, (4) Test Examples 1 and 7 to 15 in each of which the content of the hollow particles having a particle diameter of 5 μm or more was 4000 particles/10 mg or less, and (5) Test Examples 1, 2, 4 to 6, 14, and 15 in each of which, when the resin material was filled with the test sample at a solid concentration of 60% by mass, the resultant resin composition had a viscosity of 170 Pa·s or less (at a shear velocity of 1 s⁻¹).

1. A metal oxide particle material comprising a metal oxide as a main component, wherein
the metal oxide particle material has
a D50 of 1.0 μm or more and 5.0 μm or less, the D50 being obtained by measuring a laser diffraction particle size distribution,
a specific surface area of 1.0 m²/g or more and 30 m²/g or less,
a coarse particle content of 300 ppm or less, the coarse particle content being a content of coarse particles having a particle diameter of 5 μm or more, and
a hollow particle content of 4000 particles/10 mg or less, the hollow particle content being a content of hollow particles having a particle diameter of 5 μm or more, and
when a resin material is filled with the metal oxide particle material at a solid concentration of 60% by mass, a resultant resin composition has a viscosity of 170 Pas or less (at a shear velocity of 1 s⁻¹).

2. The metal oxide particle material according to claim 1 having been subjected to surface treatment with a silane compound.

3. The metal oxide particle material according to claim 1 having a hollow particle content of 4000 particles/10 mg or less, the hollow particle content being a content of hollow particles having a particle diameter of 2 μm or more.

4. The metal oxide particle material according to claim 1 having a linseed oil absorption amount of 2.7 g/15 g or less.

5. A resin composition comprising:
the metal oxide particle material according to claim 1; and
the resin material in which the metal oxide particle material has been dispersed.

6. A slurry composition comprising:
the metal oxide particle material according to claim 1; and
a dispersion medium in which the metal oxide particle material has been dispersed.

7. A metal oxide particle material production method as a method for producing the metal oxide particle material according to claim 1, the method comprising:
a production step of causing a raw particle material containing a metal for forming the metal oxide particle material as a main component to pass through a high-temperature oxidizing atmosphere to deflagrate the raw particle material, and then cooling the raw particle material to produce a raw metal oxide particle material having a D50 of 1.0 μm or more and 5.0 μm or less; and
a classification step of classifying the raw metal oxide particle material until
a content of coarse particles having a particle diameter of 5 μm or more becomes 300 ppm or less, and
a content of hollow particles having a particle diameter of 5 μm or more becomes 4000 particles/10 mg or less.

8. The metal oxide particle material production method according to claim 7, wherein the classification step includes a hollow particle separation step of dispersing the raw metal oxide particle material in a dispersion medium in liquid form and separating the hollow particles having a low specific gravity.

9. The metal oxide particle material production method according to claim 7, wherein the high-temperature oxidizing atmosphere has a temperature of 2000° C. or more.

10. A filler for a sealing material for a semiconductor package, the filler comprising the metal oxide particle material according to claim 1.
